(19) United States
(12) Patent Application Publication
(10) Pub. No.: US 2026/0246480 A1
(43) Pub. Date: Aug. 20, 2026

(54) HIGH THROUGHPUT CODING OF NEURAL NETWORK PARAMETERS

(71) Applicant: QUALCOMM Incorporated, San Diego, CA (US)

(72) Inventor: Amir Said, San Diego, CA (US)

(21) Appl. No.: 19/057,412

(22) Filed: Feb. 19, 2025

(51) Int. Cl. H03M 7/30; H03M 7/40

(52) U.S. Cl. CPC H03M 7/3077; H03M 7/40; H03M 7/6005; H03M 7/6011

(57) ABSTRACT

Certain aspects of the disclosure provide for encoding quantized data including neural network weights. Encoding can include determining bits of quantized data that are compressible and non-compressible based on one or more properties of the quantized data and performing a byte-aligned rearrangement of the bits of the quantized data. Subsequently, a compression technique can be selectively applied to at least one compressible bit, and at least one non-compressible bit can be copied. Further, the data can be decoded by identifying a compressed byte in a stream of bytes, decompressing the compressed byte, and extracting bits from the stream of bytes that encode quantized data.

### FIELD

Aspects of the subject disclosure relate to machine learning models and, more particularly, neural networks, and performance enhancement.

### BACKGROUND

Neural networks are a type of machine-learning model inspired by the human brain. Neural networks include interconnected nodes, called neurons, which can learn to perform tasks by processing data and recognizing patterns. A benefit of neural networks is their ability to learn complex non-linear relations in data through training without explicit programming.

Neural networks learn to perform tasks by adjusting the strength of connections, known as weights, between interconnected neurons. The weights represent learned parameters and encode relationships discovered in training data. The values of the weights impact performance as they determine how a neural network will respond to new inputs. In some applications, such as multimodal large language models and diffusion generative models, neural networks have a large number of weights.

### SUMMARY

The following presents a simplified summary to provide a basic understanding of some aspects of the disclosed subject matter. This summary is not an extensive overview. It is not intended to identify key/critical elements or to delineate the scope of the claimed subject matter. Its sole purpose is to present some concepts in a simplified form as a prelude to the more detailed description presented later.

Briefly described, various methods, apparatuses, and systems related to improving throughput with respect to neural network parameters are presented herein. Neural network parameters, such as weights, can be quantized and represented as integers, which reduces the size of the neural network and lowers power consumption. Quantized data can be analyzed to determine compressible and non-compressible bits to allow selective encoding or compression of more compressible portions while leaving less compressible portions uncompressed, which improves computational efficiency and enhances throughput. Furthermore, byte-aligned rearrangement of the bits of the quantized data can be performed to enable byte-centered processing and exploit underlying byte-level processing capabilities to improve performance. Additionally, processing can be fully parallelizable and may be implemented using logical SIMD (Single Instruction Multiple Data/Threads) operations, enabling high throughput. Further aspects relate to matching compressed data in group size to processor architectures and byte packing.

To the accomplishment of the foregoing and related ends, certain illustrative aspects of the claimed subject matter are described herein in connection with the following description and annexed drawings. These aspects are indicative of various ways in which the subject matter may be practiced, all of which are intended to be within the scope of the claimed subject matter. Other advantages and novel features may become apparent from the following detailed description when considered in conjunction with the drawings.

### DESCRIPTION OF THE DRAWINGS

The appended figures depict certain aspects and are therefore not to be considered limiting of the scope of this disclosure.

FIG. 1 is a block diagram illustrating an example computing device with which aspects of the subject disclosure can be performed.

FIG. 2 is a block diagram of an example coding component.

FIG. 3 is a block diagram of an example encoder.

FIG. 4 is a block diagram of an example decoder.

FIG. 5 is an example graph of a distribution of neural network weights from a large language model.

FIG. 6 illustrates an example table with transformations of bits.

FIG. 7A depicts an example code implementation of parallel sign+magnitude conversion.

FIG. 7B depicts an example code implementation of parallel sign+magnitude conversion.

FIG. 8 illustrates an example of bit rearrangement.

FIG. 9A depicts example bit permutations.

FIG. 9B depicts an example of two-stage bit permutations of FIG. 9A.

FIG. 10 illustrates example code implementing the two-stage bit permutation of FIG. 9B.

FIG. 11 illustrates an example of bit rearrangement.

FIG. 12A depicts example bit permutations.

FIG. 12B illustrates an example of two-stage bit permutations of FIG. 12A.

FIG. 13 depicts a technique for compressing rearranged data.

FIG. 14 depicts example code for implementing compression of FIG. 13.

FIG. 15 is a flow chart of an example method of encoding data.

FIG. 16 is a flow chart of an example method of decoding data.

To facilitate understanding, identical reference numerals have been used, where possible, to designate identical elements that are common to the drawings. It is contemplated that elements and features of one embodiment may be beneficially incorporated in other embodiments without further recitation.

### DETAILED DESCRIPTION

Aspects of the subject disclosure provide apparatuses, methods, processing systems, and computer-readable mediums for encoding quantized data, including neural network weights, among other things.

Some neural network applications (e.g., multimodal large language models and diffusion generative models) utilize large amounts of data, including trained weights and other network parameters. In operation, weights and other neural network parameters are moved from slow memory, such as system memory or storage, to fast processor cache or neural signal processing memory to reduce data access time and avoid introducing significant latency associated with slow memory. Nevertheless, application speed can be severely constrained by memory-to-processor throughput, for instance, due to the speed disparity between slow and fast memory as well as bus bandwidth. Further, large data movements can also significantly increase power requirements.

Compression can significantly reduce data and power requirements. However, neural network weights are frequently defined in floating-point representations, which are difficult to compress due to the complex sign+mantissa+exponent representation, and custom hardware may be the only way to achieve the required compression speeds. One alternative is to utilize integers to represent weights, which can greatly reduce the amount of data and power used. However, precision performance is degraded significantly below a threshold. Further, the advantages of compression can be negated if the coding method and implementation are relatively slow.

Aspects of the subject disclosure, address the aforementioned technical problem with a technical solution that partitions data elements into those that can and cannot be compressed and focuses computational resources on the data that can be compressed and minimal resources on the data that cannot be compressed.

In accordance with another aspect, byte-centered processing can be performed to exploit underlying byte-level processing capabilities to achieve optimized performance by minimizing overhead and inefficiencies that can arise from working with data that does not align well with processing resources. In one instance, coding transformation can be fully parallelizable and may be implemented using logical SIMD (Single Instruction Multiple Data/Threads) operations (e.g., AND, OR, XOR, and bit shifts) that are universally available.

In accordance with another aspect, a mechanism generates compressed data in group sizes, such as 8- or 32-bit integers, that match the current processor architectures. As a result, the number of slow bitwise operations can be minimized, enabling the use of faster entropy coding methods.

Aspects of the disclosure include a coding process that can yield high data throughputs, with compression ratios that are only slightly inferior to more complex and slower compression methods. Further, fast coding speed can be achieved by exploiting byte-level processing and parallelization techniques, such as multi-core and Single Instruction Multiple Data/Threads SIMD architectures. Efficiency can also be improved by representing weights as integers and selectively compressing weight values since it reduces data bandwidth and the power needed for copying weights. Furthermore, matching compressed data group sizes to current architectures ensures efficient use of SIMD instructions, memory alignment, and cache utilization, enabling faster data processing, minimizing power consumption, and avoiding wasted bandwidth.

### Example Computing Device

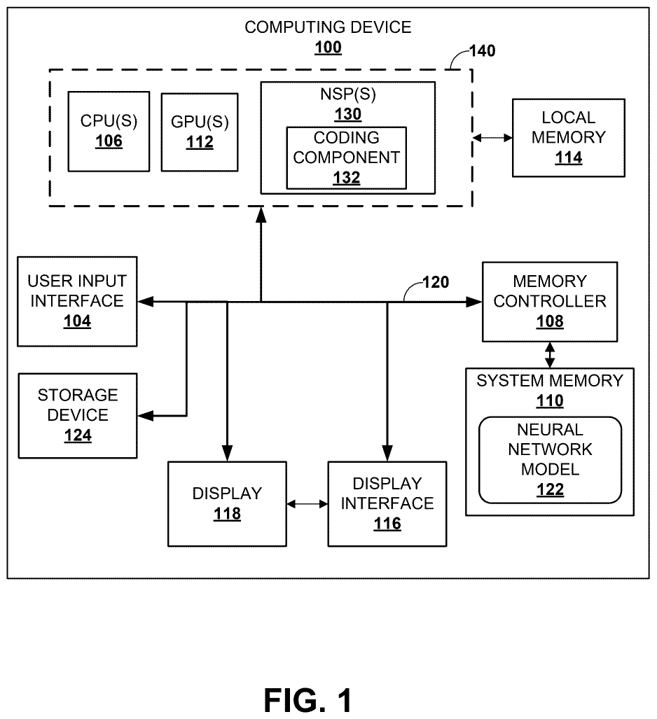

FIG. 1 is a block diagram illustrating an example computing device that may perform techniques of this disclosure. Computing device 100 may comprise a mobile device such as a smart phone, a mobile telephone, a cellular telephone, a satellite telephone, or a mobile telephone handset. Further, the computing device 100 may comprise a personal computer, a desktop computer, a laptop computer, a computer workstation, a video game platform or console, a landline telephone, an Internet telephone, a handheld device such as a portable video game device or a personal digital assistant (PDA), a personal music player, a video player, a display device, a television, a television set-top box, a server, an intermediate network device, a mainframe computer, a mobile computing device, a vehicle head unit, self-driving or autonomous driving vehicle, or a robot.

As illustrated in the example of FIG. 1, computing device 100 includes a user input interface 104, CPU(S) 106, memory controller 108, system memory 110, graphics processing unit (GPU) 112, neural network signal processor (NSP) 130, coding component 132, which may be implemented in NSP(S) 130, local memory 114, display interface 116, display 118, bus 120, and storage device(s) 124. User input interface 104, CPU(S) 106, memory controller 108, GPU(S) 112, coding component 132, NSP(S) 130, display interface 116, and storage device(s) 124 may communicate with each other using bus 120. Bus 120 may be any of a variety of bus structures, such as a third-generation bus (e.g., a HyperTransport bus or an InfiniBand bus), a second-generation bus (e.g., an Advanced Graphics Port bus, a Peripheral Component Interconnect (PCI) Express bus, or an Advanced eXentisible Interface (AXI) bus) or another type of bus or device interconnect. It should be noted that the specific configuration of buses and communication interfaces between the different components shown in FIG. 1 is merely exemplary, and other configurations of computing devices and/or other graphics processing systems with the same or different components may be used to implement the techniques of this disclosure.

CPU(s) 106 may comprise one or more general-purpose and/or special-purpose processors that controls operation of computing device 100. A user may provide input to computing device 100 to cause CPU(s) 106 to execute software including one or more of system software and application software. System software executing on CPU(s) 106 can manage and control computer hardware and provide a platform for running application software. Examples of system software may include an operating system, firmware, device drivers, and virtualization platforms. Application software, or software applications, that execute on CPU(s) 106 may include, for example, a word processor application, an email application, a spreadsheet application, a media player application, a video game application, a graphical user interface application, or other programs. The user may provide input to computing device 100 by way of one or more input devices (not shown), such as a keyboard, a mouse, a microphone, a touchpad, or another input device that is coupled to computing device 100 by way of the user input interface 104.

Memory controller 108 facilitates the transfer of data going into and out of system memory 110. For example, memory controller 108 may receive memory read and write commands, and service such commands with respect to system memory 110 to provide memory services for the components in computing device 100. Memory controller 108 is communicatively coupled to system memory 110. Although memory controller 108 is illustrated in the example computing device 100 of FIG. 1 as being a processing module that is separate from both CPU(s) 106 and system memory 110, in other examples, some or all of the functionality of memory controller 108 may be implemented on one or both of CPU(s) 106 and system memory 110.

System memory 110 may store program modules and/or instructions that are accessible for execution by CPU(s) 106 and/or data for use by the programs executing on CPU(s) 106. For example, system memory 110 may store user applications and graphics data associated with the applications. System memory 110 may additionally store information for use by and/or generated by other components of computing device 100. For example, system memory 110 may act as a device memory for one or more GPU(s) 112 and may store data to be operated on by GPU(s) 112 as well as data resulting from operations performed by GPU(s) 112. System memory 110 may include one or more volatile or non-volatile memories or storage devices, such as, for example, random access memory (RAM), static RAM (SRAM), dynamic RAM (DRAM), read-only memory (ROM), erasable programmable ROM (EPROM), electrically erasable programmable ROM (EEPROM), flash memory, a magnetic data media or an optical storage media.

In some aspects, system memory 110 may include instructions that cause CPU(s) 106, GPU(s) 112, or NSP(s) 130 to perform the functions described in this disclosure to CPU(s) 106, GPU(s) 112, and NSP(s) 130. Accordingly, system memory 110 may be a computer-readable storage medium having instructions stored thereon that, when executed, cause one or more processors (e.g., CPU(s) 106, GPU(s) 112, NSP(s) 130) to perform various functions.

In some examples, system memory 110 is a non-transitory storage medium. The term “non-transitory” indicates that the storage medium is not embodied in a carrier wave or a propagated signal. However, the term “non-transitory” should not be interpreted to mean that system memory 110 is non-movable or that its contents are static. As one example, system memory 110 may be removed from computing device 100, and moved to another device. As another example, memory, substantially similar to system memory 110, may be inserted into computing device 100. In certain examples, a non-transitory storage medium may store data that can, over time, change (e.g., in RAM).

Storage device(s) 124 may include removable/non-removable, volatile/non-volatile storage media for storing vast amounts of data relative to system memory 110. For example, storage device(s) 124 may include, but are not limited to, one or more devices such as a magnetic or optical disk drive, flash memory, solid-state drive, or memory stick. Data may be saved or persisted to the storage device(s) 124 and later retrieved and loaded into system memory 110 for further processing. In accordance with one aspect of the subject disclosure, neural network values such as parameters, weights, and biases can saved to the storage device(s) 124.

GPU(s) 112 may be configured to perform graphics operations to render one or more graphics primitives to display 118. Thus, when one of the software applications executing on CPU(s) 106 requires graphics processing, CPU(s) 106 may provide graphics commands and graphics data to GPU(s) 112 for rendering to display 118. The graphics commands may include, e.g., drawing commands such as a draw call, GPU state programming commands, memory transfer commands, general-purpose computing commands, kernel execution commands, etc. In some examples, CPU(s) 106 may provide the commands and graphics data to GPU(s) 112 by writing the commands and graphics data to system memory 110, which may be accessed by GPU(s) 112. In some examples, GPU(s) 112 may be further configured to perform general-purpose computing for applications executing on CPU(s) 106.

GPU(s) 112 may, in some instances, be built with a highly parallel structure that provides more efficient processing of vector operations than CPU(s) 106. For example, GPU(s) 112 may include a plurality of processing elements that are configured to operate on multiple vertices or pixels in a parallel manner. The highly parallel nature of GPU(s) 112 may, in some instances, allow GPU(s) 112 to draw graphics images (e.g., GUIs and two-dimensional (2D) and/or three-dimensional (3D) graphics scenes) onto display 118 more quickly than drawing the scenes directly to display 118 using CPU(s) 106. In addition, the highly parallel nature of GPU(s) 112 may allow GPU(s) 112 to process certain types of vector and matrix operations for general-purpose computing applications more quickly than CPU(s) 106. In some examples, computing device 100 may make use of the highly parallel structure of GPU(s) 112 to perform parallel entropy coding.

GPU(s) 112 may, in some instances, be integrated into a motherboard of computing device 100. In other instances, GPU(s) 112 may be present on a graphics card that is installed in a port in the motherboard of computing device 100 or may be otherwise incorporated within a peripheral device configured to interoperate with computing device 100. In further instances, GPU(s) 112 may be located on the same microchip as CPU(s) 106 forming a system on a chip (SoC). GPU(s) 112 and CPU(s) 106 may include one or more processors, such as one or more microprocessors, application specific integrated circuits (ASICs), field programmable gate arrays (FPGAs), digital signal processors (DSPs), or other equivalent integrated or discrete logic circuitry.

CPU(s) 106, GPU(s) 112, and NSP(s) 130 may together be referred to as one or more processors 140. In describing the various techniques that may be performed by one or more processors 140, it should be understood that such techniques may be performed by one or more of CPU(s) 106, GPU(s) 112, and NSP(s) 130. It should be understood that the techniques disclosed herein are not necessarily limited to being performed by CPU(s) 106, GPU(s) 112, or NSP(s) 130, but may also be performed by any other suitable hardware, device, logic, circuitry, processing units, and the like of computing device 100.

GPU(s) 112 may be directly coupled to local memory 114. Thus, GPU(s) 112 may read data from and write data to local memory 114 without necessarily using bus 120. In other words, GPU(s) 112 may process data locally using a local storage, instead of off-chip memory. This allows GPU(s) 112 to operate in a more efficient manner by eliminating the need of GPU(s) 112 to read and write data via bus 120, which may experience heavy bus traffic. In some instances, however, GPU(s) 112 may not include a separate cache, but instead utilize system memory 110 via bus 120. Local memory 114 may include one or more volatile or non-volatile memories or storage devices, such as, e.g., random access memory (RAM), static RAM (SRAM), dynamic RAM (DRAM), erasable programmable ROM (EPROM), electrically erasable programmable ROM (EEPROM), flash memory, a magnetic data media or an optical storage media.

As described, CPU(s) 106 may offload graphics processing to GPU(s) 112, such as tasks that require massive parallel operations. As one example, graphics processing requires massive parallel operations, and CPU(s) 106 may offload such graphics processing tasks to GPU(s) 112. However, other operations such as matrix operations may also benefit from the parallel processing capabilities of GPU(s) 112. In these examples, CPU(s) 106 may leverage the parallel processing capabilities of GPU(s) 112 to cause GPU(s) 112 to perform non-graphics related operations.

CPU(s) 106, GPU(s) 112, and NSP(s) 130 may store rendered image data in a frame buffer that is allocated within system memory 110. Display interface 116 may retrieve the data from the frame buffer and configure display 118 to display the image represented by the rendered image data. In some examples, display interface 116 may include a digital-to-analog converter (DAC) that is configured to convert the digital values retrieved from the frame buffer into an analog signal consumable by display 118. In other examples, display interface 116 may pass the digital values directly to display 118 for processing.

Display 118 may include a monitor, a television, a projection device, a liquid crystal display (LCD), a plasma display panel, a light emitting diode (LED) array, a cathode ray tube (CRT) display, electronic paper, a surface-conduction electron-emitted display (SED), a laser television display, a nanocrystal display, an organic light-emitting-diode (OLED) display, or another type of display unit. Display 118 may be integrated within computing device 100. For instance, display 118 may be a screen of a mobile telephone handset or a tablet computer. Alternatively, display 118 may be a stand-alone device coupled to computing device 100 via a wired or wireless communications link. For instance, display 118 may be a computer monitor or flat panel display connected to a personal computer via a cable or wireless link.

System memory 110 may store neural network model 122. Neural network model 122 may include one or more artificial neural networks (also referred to as neural networks) trained to receive input data of one or more types and to, in response, provide output data of one or more types.

A neural network (e.g., neural network model 122) may include a trainable or adaptive algorithm that utilizes nodes to transform inputs into outputs through learned parameters and activation functions. Each node can apply a mathematical function, such as a non-linear activation function, to process input data. Neural networks typically do not explicitly define logical rules, such as if-then rules. However, specialized or hybrid systems may incorporate rule-based reasoning alongside neural network structures.

A neural network may include three types of layers of nodes, namely an input layer, one or more hidden layers, and an output layer. The input layer may receive inputs, such as values from which the neural network as a whole generates an output. The output of each node of the input layer may be provided to each node of a first layer of hidden layers. Each input from the input layer may be multiplied by a neural network weight and then summed at each node of hidden layers. Such weights are determined or adjusted during training of neural network to establish a relationship between the input data and output data. Output of each node of the first hidden layer are provided to each node of a next hidden layer, and so on, when there are more than one hidden layer. The output layer may be provided with the output of each node of the last hidden layer. The output layer may include a transfer function and may output an inference, prediction, classification, etc. which is based on the input data and the neural network weights.

A respective node of a plurality of nodes of a layer may be connected to one or more different nodes of the plurality of nodes along an edge, such that the output of the respective node includes the input of the different node. The functions may include neural network weights that may be determined or adjusted using a training set of inputs and desired outputs along with a learning rule, such as a back-propagation learning rule. The back-propagation learning rule may utilize one or more error measurements comparing the desired output to the output produced by the neural network to train the neural network by varying the parameters to minimize the one or more error measurements.

In some examples, neural network model 122 is trained to perform classification of input data. That is, neural network model 122 may be trained to label input data to classify input data into one or more classes or categories. Neural network model 122 may perform classification of input data by determining, for the input data, a confidence score for each of a plurality of classes that indicates a degree to which it is believed that the input data should be classified into the corresponding class. In other examples, neural network model 122 may determine a probabilistic distribution over a set of classes to indicate the probability that the input data belongs to each of the set of classes.

In some examples, neural network model 122 may be trained to perform computer vision tasks such as image classification, object detection, and/or image segmentation. Such computer vision tasks may be useful for computer vision applications such as autonomous driving. For example, neural network model 122 may be trained to perform image classification to determine which objects are in an image or video, such as by being trained to classify an image as either including a particular object or not including the particular object and by assigning one or more labels to the image. In another example, neural network model 122 may be trained to perform object detection to detect what objects are in an image or video and to specify where each of the objects is in the image, and neural network model 122 may be trained to assign one or more labels to each of the one or more objects in the image. In some examples, neural network model 122 may be trained to perform image segmentation to separate an image into regions that delineate potentially meaningful areas for further processing.

Coding component 132 is configured to perform coding, which can include encoding and decoding techniques, with respect to neural network values, such as parameters, weights, or biases. In one instance, the neural network values can include quantized data that represents weights and biases, or the like, typically represented as floating point numbers, as integers. In accordance with one aspect, the coding component 132 can be employed to encode a trained neural network model, such as neural network model 122 to save the neural network values to storage device 124, system memory 110, or both. The encoded neural network values can reduce the amount of data to be transferred and stored. In one instance, encoded neural network values can be moved from storage device 124 or system memory 110 to fast memory such as local memory 114. The encoded neural network values can be decoded by the coding component 132 during model loading into system memory 110 or local memory or at runtime on demand or as needed.

In accordance with one aspect, coding component 132 can form part of the NSP 130 as depicted. According to other aspects, the coding component 132 can be implemented external to the NSP 130, for example as part of the memory controller 108, the storage device 124, or a separate independent component. Further, the coding component 132 may be implemented with any of a suitable variety of circuitry, such as one or more microprocessors, digital signal processors (DSPs), application specific integrated circuits (ASICs), field programmable gate arrays (FPGAs), discrete logic, software, hardware, firmware, or any combinations thereof. When the techniques are implemented partially in software, a device may store instructions for the software in a suitable, non-transitory computer-readable medium and execute the instructions in hardware using one or more processors to perform the techniques of this disclosure.

### Example Coding Component

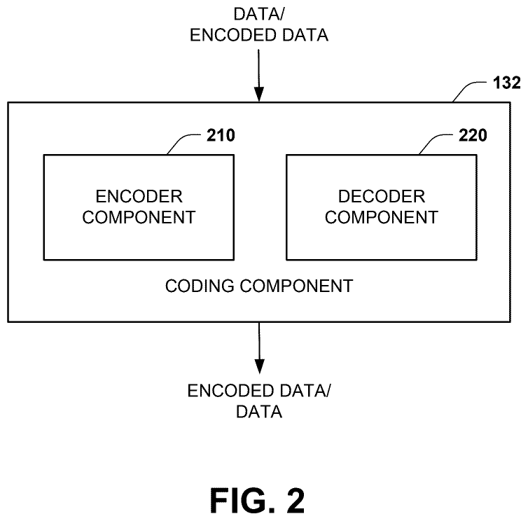

FIG. 2 is a block diagram of coding component 132. As depicted, the coding component 132 includes encoder component 510 and decoder component 220. Encoder component 210 and the decoder component 220 each may be implemented as any of a variety of suitable encoder and/or decoder circuitry, such as one or more microprocessors, digital signal processors (DSPs), neural signal processors (NSPs), application specific integrated circuits (ASICs), field programmable gate arrays (FPGAs), discrete logic, software, hardware, firmware or any combinations thereof. When the techniques are implemented partially in software, the encoder component 210 and the decoder component 220 can be implemented by at least one processor coupled to at least one memory that stores instructions that, when executed by the at least one processor, cause the processor to perform the functionality of each component to implement the coding component 132. Coding component 132 can obtain data such as raw unencoded data as input and output encoded data or receive encoded data as input and return unencoded data as output. Encoder component 210 is operable to perform encoding of data, for example, utilizing entropy encoding. Decoder component 220 is operable to decode encoded data, for instance, utilizing entropy decoding. In accordance with one aspect, the encoder component 210 and decoder component 220 can operate over quantized data such as neural network weights or parameters, for example, represented as integers. However, aspects of the disclosure have broader applications beyond neural networks. For example, aspects of the disclosure may be applicable to any situation involving compression and decompression with respect to media data (e.g., image, audio, video).

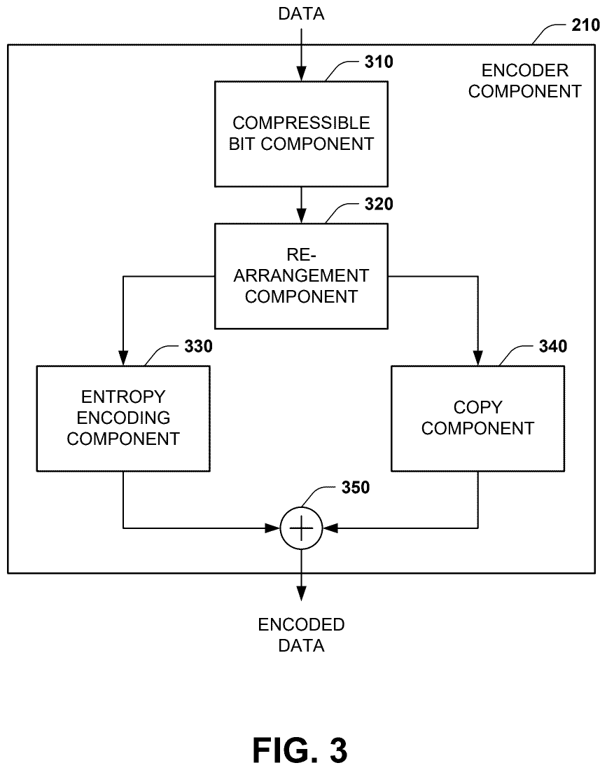

FIG. 3 is a block diagram of an example encoder component 210 operable to encode data. Encoder component 210 includes compressible bit component 310, rearrangement component 320, entropy encoding component 330, copy component 340, and union operator 350. Encoder component 210 receives unencoded data as input and outputs data where at least a subset of the data is encoded. In accordance with one aspect, unencoded data can correspond to quantized data representing neural network parameters, such as weights and biases.

Compressible bit component 310 is operable to identify compressible and non-compressible bits from the input data. In accordance with one aspect, the bits can correspond to quantized data. In one instance, input data can be specified as integer values. In another instance, the compressible bit component 310 or another component can convert floating point numbers to integers. In one instance, the compressible bit component 310 can determine the entropy of bits, and the entropy can be compared with a threshold to determine whether a bit is compressible or non-compressible. Entropy can refer to a measure of uncertainty or randomness associated with a bit. The higher the uncertainty, the higher the entropy. If a bit has low entropy, the bit is more compressible, and high entropy is less compressible. The threshold can set a particular measure of entropy that corresponds to compressible, non-compressible, or both. For example, if bit entropy satisfies the threshold, the bit can be deemed compressible or non-compressible.

Rearrangement component 320 is operable to perform a byte-aligned rearrangement of the bits of the quantized data. In accordance with one aspect, rearrangement component 320 can break the data into bit lines and stack the bit lines in order of significance, for example from the least significant bit to the most significant. For example, the top layer in the stack can hold the most important information while the bottom layer of the stack holds less important information, such as fine detail. In accordance with one aspect, the bit line is analogous to a bit plane associated with bit rearrangement compression of images. However, rather than a plane of two dimensions of image height and width, the bit line can hold a single dimension, such as weight. In accordance with another aspect, rearrangement component 320 can also organize bits into byte-size units, for example, corresponding to units supported by an executing system. Rearrangement component 320 can output bytes including bits that are compressible and non-compressible. Examples are provided later herein to aid clarity and understanding.

Entropy encoding component 330 obtains zero or more bytes that comprise compressible bits from the rearrangement component 320. Entropy encoding component 330 can subsequently apply entropy encoding to the compressible bits. Entropy encoding is a lossless data compression technique that is based on statistical properties of the data being compressed. In one instance, entropy encoding component 330 can employ Huffman coding. Generally, Huffman coding can involve analyzing the frequency of each symbol in data and generating variable-length binary codes for each symbol, for instance, such that shorter codes are assigned to frequent symbols and longer codes to infrequent symbols. Other techniques can also be employed to compress compressible bits, such as, but not limited to, arithmetic coding.

Copy component 340 is operable to copy or save bytes that comprise non-compressible bits. Copy component 340 can receive the bytes that comprise non-compressible bits from rearrangement component 320 and transmit the bytes to the union operator 350. In accordance with one implementation, the bytes comprising non-compressible bits can be transmitted directly to the union operator 350 from the rearrangement component 320. Utilizing copy component 340 facilitates process timing and data alignment.

Union operator 350 is operable to combine bytes including compressed data from the entropy encoding component with bytes including uncompressed data from copy component 340. The output of union operator 350 is encoded data. Here, the encoded data can include at least a subset of encoded data. The encoded data can also include bytes that remain unencoded together with bytes with encoded data.

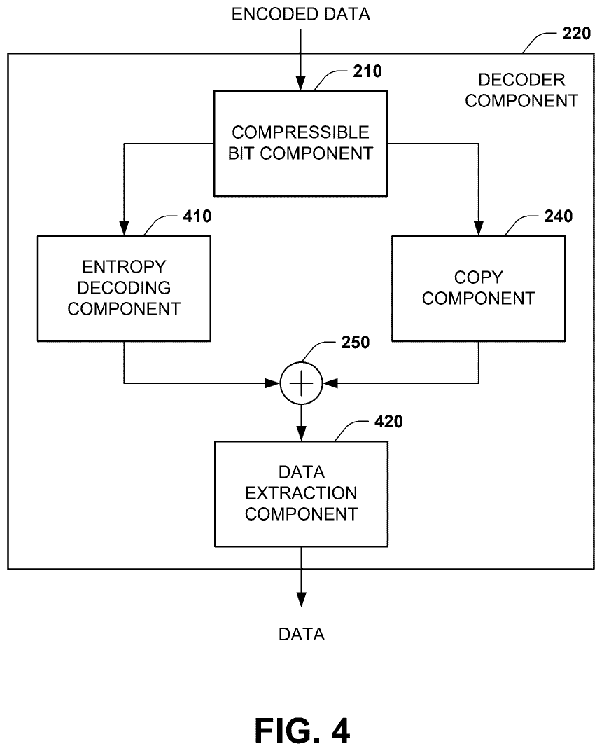

FIG. 4 is a block diagram of example decoder component 220 operable to decode encoded data, for instance, produced by encoder component 210. Decoder component 220 receives encoded data and decodes the encoded data to produce unencoded data, or simply data, as output. Decoder component 220 includes compressible bit component 310, entropy decoding component 410, copy component 240, union operator 250, and data extraction component 420.

Compressible bit component 310 can receive encoded data, for example, in the form of a series or stream of bytes. Compressible bit component 310 can determine which bytes, if any, comprise encoded or compressible bits and which bytes do not comprise encoded or compressible bits. Compressible bit component 310 can analyze the bytes and, optionally, information related to the bytes to make such a determination. For example, header information may indicate which bytes are encoded and which bytes are not encoded. Encoded bytes can be provided to the entropy decoding component 410 unencoded bytes can be provided to copy component 240.

Entropy decoder component 410 is operable to reconstruct original data from an encoded version. In other words, entropy decoder component 410 is operable to reverse an encoding process to recover original data. Entropy decoder component 410 can employ encoding rules to map an encoded byte back to the original unencoded byte. For example, Huffman encoding rules may be employed to decode an encoded byte.

Copy component 240 is operable to copy or save unencoded bytes identified by the compressible bit component 310.

Union operator 250 is configured to combine unencoded bytes from entropy decoding component 410 and copy component 240. The result is a sequence or stream of bytes.

Data extraction component 420 is operable to extract original data from a byte stream. Original data may have been rearranged and byte aligned. Data extraction component 420 can reverse a rearrangement process to produce original data. Output of the data extraction component 420 can be original integer values of neural network parameters such as weights.

### Example Coding Implementations

The following is a discussion of specific implementations of aspects of the subject disclosure to facilitate further clarity and understanding. These implementations are examples of coding described herein. Of course, this disclosure is not limited to the example coding implementations as additional implementations are possible and contemplated.

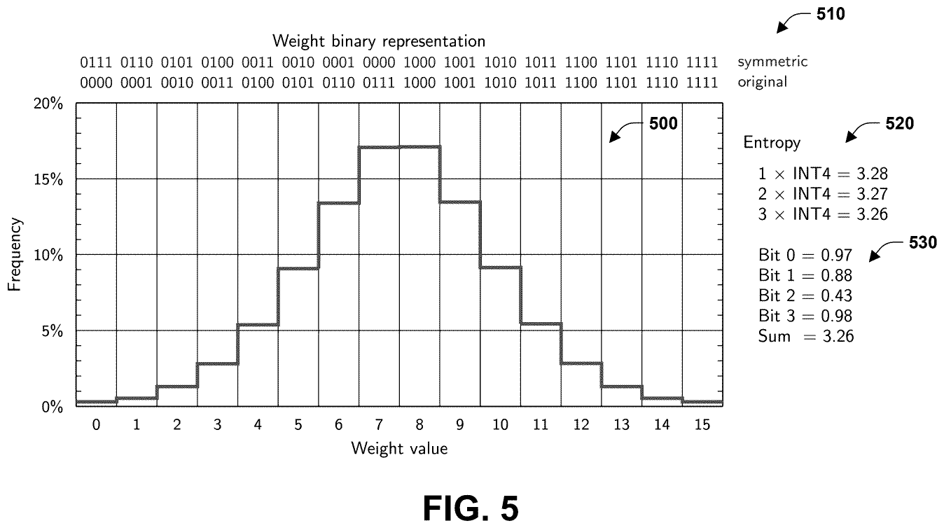

FIG. 5 depicts a graph 500 of a distribution of neural network weights from a large language model (LLM). Graph 500 illustrates neural network weights quantized to four bits (INT4). Each horizontal segment corresponds to a range of floating-point numbers being mapped to a single quantized integer. Quantization reduces precision but also reduces size to enable efficient storage and computation. At 510, weighted binary representations are shown for the original representation and a symmetric representation. The symmetric representation ensures a range of positive and negative quantization levels centered around zero, which can be significant for neural network weights that are also zero-centered.

Integer weights can be easier to process than floating point weights. However, neural network weights are much less compressible than multimedia data, for example. The floating-point distribution is similar to a Gaussian symmetric distribution, which alone is not very compressible. Further, computed high-order entropies at 520 indicate that very little extra compression can be obtained by increasing the complexity of the compression method.

The sums of bit entropies shown at 520 are nearly equal to the fourth-order weight value entropy (4.0), demonstrating that the weights are very nearly independent and there is little compression loss if those bits are coded independently. As shown at 530, with one exception, the entropy of the bits is nearly the maximum (1 bit/symbol), meaning they cannot be significantly compressed with any form of entropy encoding. Thus, it is more efficient to apply entropy encoding to bit two (with entropy 0.43 bit/symbol) and not change the remaining bits.

A symmetry in the distributions of an integer network weight w, represented with B bits of precision, is defined by

$$Prob ( w = n ) \approx Prob ( w = {2}^{B} - 1 - n ) , \qquad ( 1 )$$

which can be observed in FIG. 5, where B=4. This symmetry can be used to simplify compression, and it can be more easily exploited for individual bits by converting the unsigned integer weight representation to one similar to a sign+magnitude representation. Using the following notation for a sequence of B bits in the integer binary representation of a weight can be defined as:

$$w = {\sum }_{k = 0}^{B - 1} {2}^{k} {r}_{k} , {r}_{k} ∈ \{ 0 , 1 \} . \qquad ( 2 )$$

The following transformation can be used:

$${s}_{k} ( w ) = \{ \text{} \begin{matrix}{r}_{k} ⊕ {\overline{r}}_{B - 1} , & k < B - 1 , \\ {r}_{k} , & k = B - 1.\end{matrix} \text{} \qquad ( 3 )$$

where the bar (a) denotes binary complement and a⊗b represents the exclusive-or (XOR) binary operation, for example for a, b∈{0,1}:

$$a ⊕ b = \{ \text{} \begin{matrix}0 , & a = b , \\ 1 , & a \neq b .\end{matrix} \text{}$$

The transformation complements the least significant bits if the most significant bit is zero. Since complementing the same bits again gives the original bit values, it is an involution, where the transform is equal to its inverse.

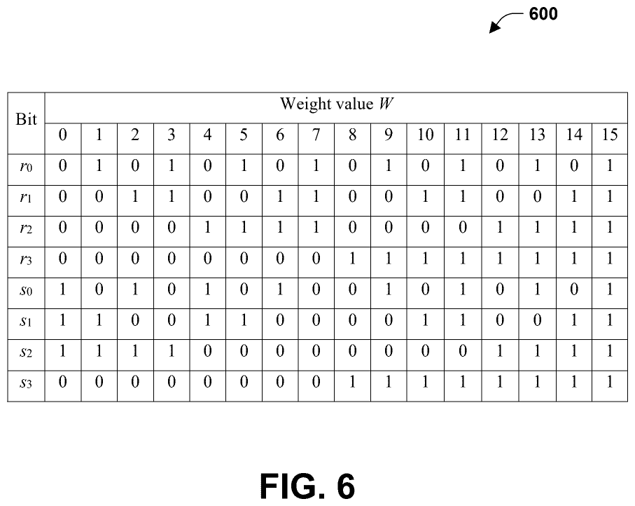

FIG. 6 depicts a table 600 with transformation of equation (3), of bits wₖ from the integer binary representation of weights W with B=4 bits, to the bits sₖ of a sign+magnitude representation. Table 600 shows the binary values of this transformation for B=4 bits, where we can observe that

$${s}_{k} ( w ) = {s}_{k} ( {2}^{B} - 1 - w ) ,$$

$$k = 0 , 1 , … , B - 2 ,$$

That is, the modified bits are matched to the symmetry defined by equation (1).

This conversion can be prohibitively slow when the bits in each weight value are processed individually, but can be greatly accelerated using processor instructions that operate on bits from many aggregated weight values.

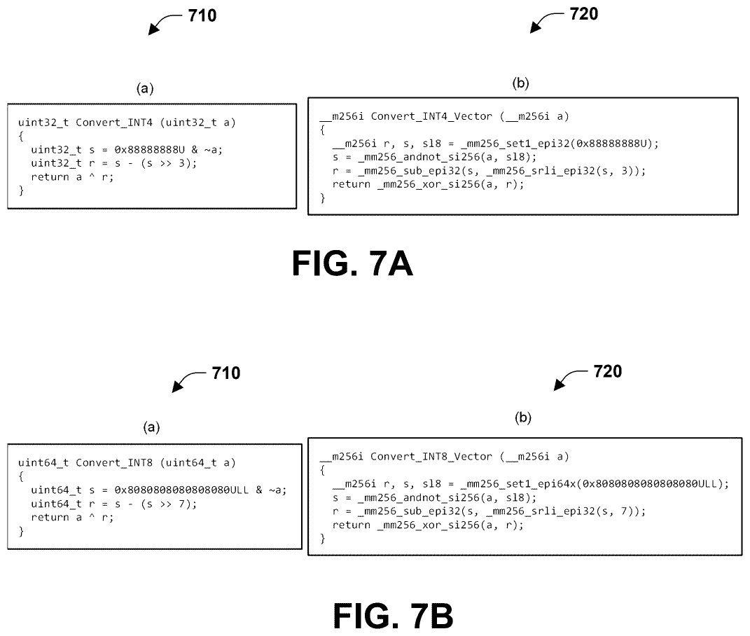

FIG. 7A shows C++ implementation code operating on 32-bit integers that contain 8 4-bit weight values, at 710. In this code, the logical and arithmetic operations generate the 32-bit values that correspond to the bits needed for computing the transformation of equation (3) above. This approach can be directly extended to processor instructions that operate on a larger number of bits.

FIG. 7A also shows the code implementing the same transformation, but using 256-bit registers containing 64 4-bit weight values, at 720. In this case the operations are not part of the C++ standard, and this example employs Intel's AVX2 vector operations (SIMD instructions). FIG. 7B depicts the same type of code, but for weights with precision B=8 bits.

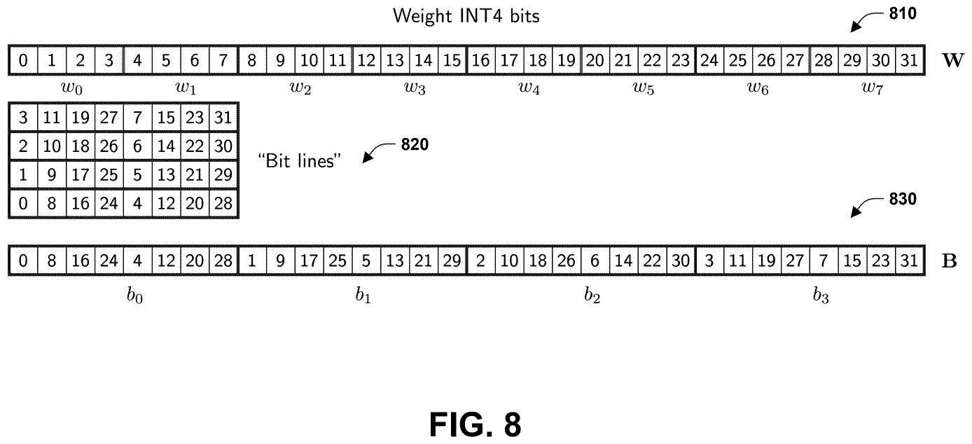

FIG. 8 illustrates an example bit rearrangement implemented by the rearrangement component 320. More specifically, FIG. 8 shows bit separation according to significance can be done to groups of eight four-bit (8 INT4) weights 810 to obtain eight-bit bytes corresponding to bit lines 820. Subsequently, the bit lines 820 ordered by significance can be utilized to produce four eight-bit bytes of data 830. Bit rearrangement can be simple and intuitive. However, processing individual bits is prohibitively slow, meaning that this transformation cannot be useful without an efficient way of rearranging the bits.

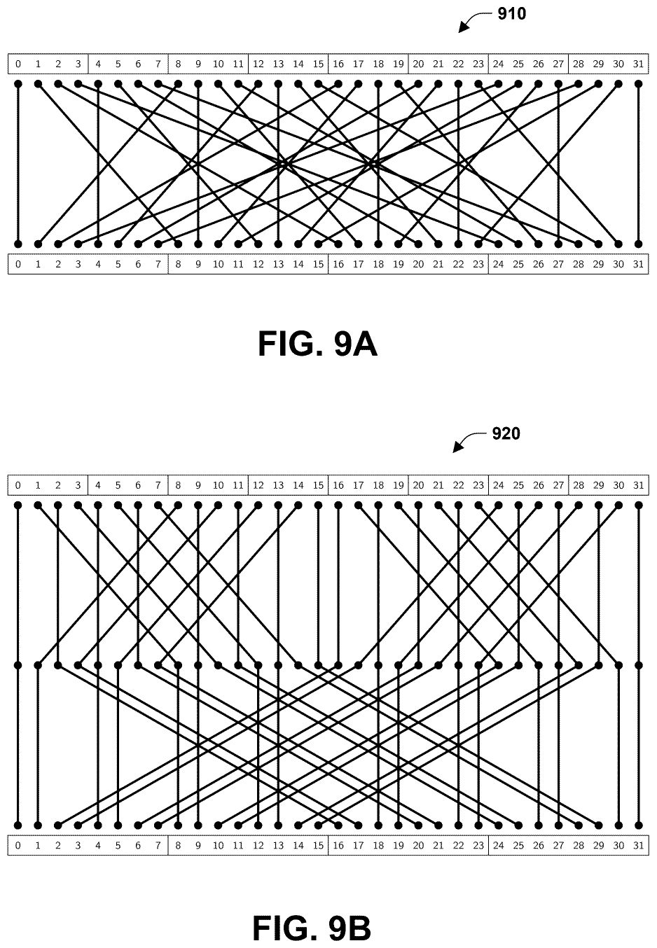

FIG. 9A depicts bit permutations 910 needed to obtain the conversion in FIG. 8. More specifically, FIG. 9A illustrates bit permutations 910 from a group of 8×INT4 elements to four bytes including the same significance bits. In accordance with one aspect, the permutations 910 can be implemented using bit shift instructions. The set of bit shifts can be arranged in a Matix A as:

$$S = [ \text{} \begin{matrix}0 & 7 & 14 & 21 \\ - 7 & 0 & 7 & 14 \\ - 14 & - 7 & 0 & 7 \\ - 21 & - 14 & - 7 & 0\end{matrix} \text{} ] \qquad MATRIX A$$

Here, positive values represent right shifts, and negative values represent left shifts. There are seven different bit shifts used to perform the bit permutations 910 in a single stage with all shifts combined.

FIG. 9B depicts bit permutations 910 of FIG. 9A implemented as two stage permutations 920. In accordance with one aspect, bit shifts are multiples of seven, and permutations can be combined in multiple stages. FIG. 9B shows two stages that can be computed in 32-bit words with bit shifts and logical operations. The first permutation stage uses bit shifts with values (−7, 0, 7), and the second bit shifts with values (−14, 0, 14), requiring a smaller number of operations. Since the permutation system of FIG. 9B only needs bit shifts and binary logic operations “AND” and “OR”, the permutation can be efficiently computed in parallel using single-instruction multiple-data (SIMD) operations.

The aforementioned permutations are similar to matrix transposition. That is, the permutations perform swaps on pairs of bits. Thus, in the same way that transposing a matrix twice results in the original matrix, applying those bit permutations twice result in no change. This means that these transformations are involutions, and the same implementation can be used for forward and inverse transformations.

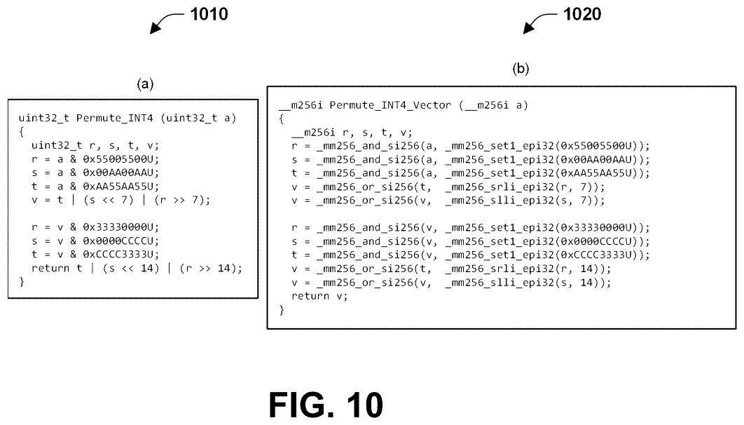

FIG. 10 shows examples of code implementing the change in weight binary representation, and the proposed two stage bit permutation, shown in FIG. 9B. At 1010, FIG. 10 shows an implementation using standard C++ bit shifts and binary operations applied to 32-bit integers. At 1020, FIG. 10 shows the corresponding implementation applied to vectors with 8×32-bit integers, where each function represents a SIMD vector instruction using intrinsic functions for Intel's AVX2 parallel execution (256-bit registers).

In the context of fast compression, we can note that not only the operations never need to process individual bits, but in fact they can operate simultaneously on all bits available to a SIMD register. For instance, Qualcomm's HVX processor has 1024-bit registers, and thus can process in a single instruction 256 INT4 weight values.

The techniques described above can be extended to other integer precisions, such as eight-bit weights (INT8).

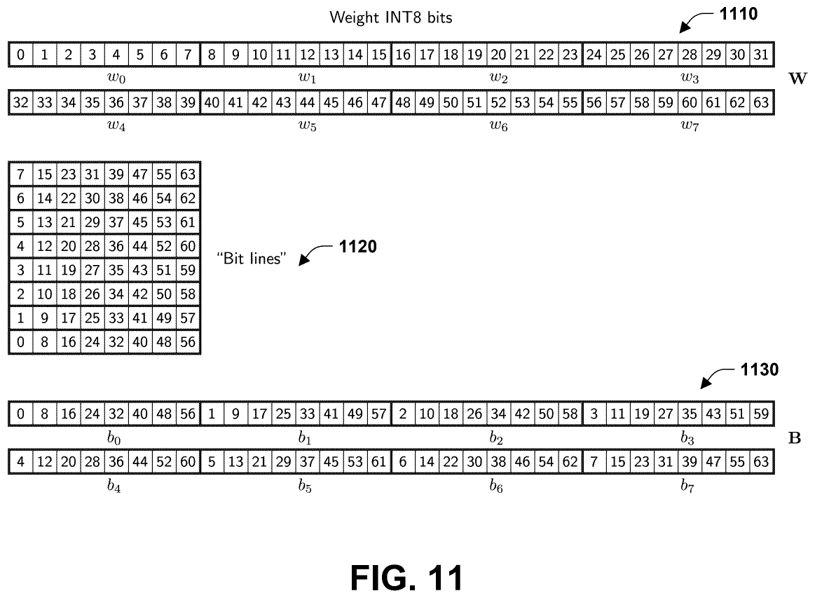

FIG. 11 illustrates an example bit rearrangement implemented by the rearrangement component 320. More specifically, FIG. 11 shows bit separation according to significance can be done to groups of eight eight-bit (8 INT4) weights 1110 to obtain eight-bit bytes corresponding to bit lines 1120. Subsequently, the bit lines 1120 ordered by significance can be utilized to produce eight eight-bit bytes of data 1130. In accordance with one aspect, the permutation can be implemented using bit shift instructions. The set of bit shifts can be arranged in a Matrix B as:

$$S = [ \text{} \begin{matrix}0 & 7 & 14 & 21 & 28 & 35 & 42 & 49 \\ - 7 & 0 & 7 & 14 & 21 & 28 & 35 & 42 \\ - 14 & - 7 & 0 & 7 & 14 & 21 & 28 & 35 \\ - 21 & - 14 & - 7 & 0 & 7 & 14 & 21 & 28 \\ - 28 & - 21 & - 14 & - 7 & 0 & 7 & 14 & 21 \\ - 35 & - 28 & - 21 & - 14 & - 7 & 0 & 7 & 14 \\ - 42 & - 35 & - 28 & - 21 & - 14 & - 7 & 0 & 7 \\ - 49 & - 42 & - 35 & - 28 & - 21 & - 21 & - 14 & 0\end{matrix} \text{} ] \qquad MATRIX B$$

Again, the matrix elements are multiples of seven, meaning the same type of factorization utilized for INT4 can be used again for INT8, but with an extra pass with bit shift values (−28, 0, 28). The first two passes can be equal to those of FIG. 9B, but with 64-bit words.

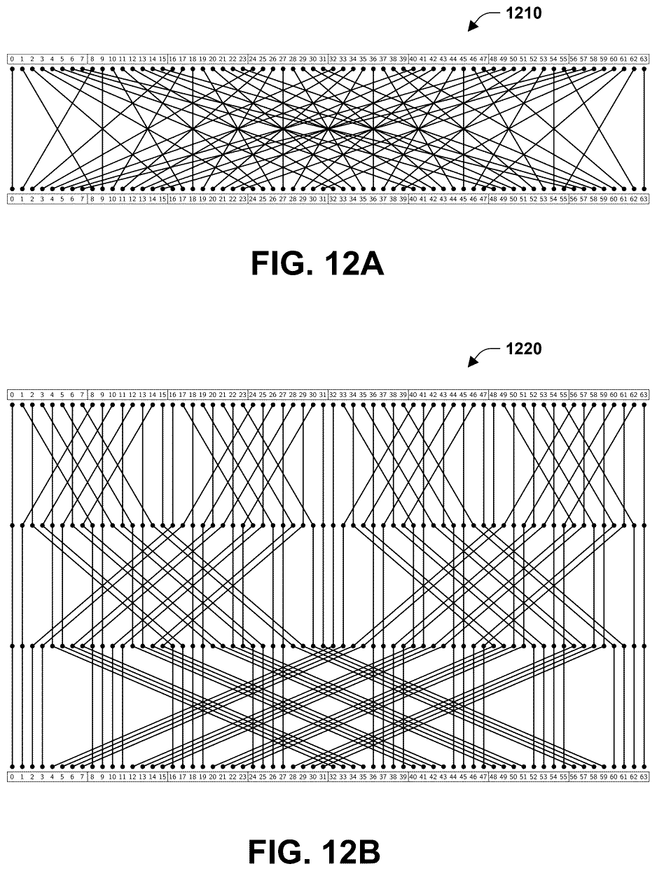

FIG. 12A depicts bit rearrangement or permutations 1210 from a group of 8×INT8 elements to 8 bytes with the same significance bits. FIG. 12A is thus the INT8 version of bit permutation 910 of FIG. 9A.

FIG. 12B illustrates bit rearrangements or permutations 1220 of FIG. 12A implemented with three stages that can be computed in 64-bit words with solely bit-shifts and logical operations.

Example byte rearrangements described above can be extended. In general, the permutations of bits in groups of integers with 2^{p} bits of precision can utilize “P” stages each with bit shifts in the set

$${\{ 0 \} ⋃ ( 7 \times {2}^{p} \}}_{p = 0}^{P - 1} .$$

The size of the words used for bit shifts may vary, but as shown in FIG. 12B each stage has groups of 1, 2, and 4 bits being shifted together. The next stages have multiples of 8 bits being moved, which corresponds to byte permutations instead of bit permutations. Those do not need bit shift instructions, but instead can use SIMD byte permutation instructions, or simply use memory address offsets for the byte permutations.

The fast scheme for bit permutations described above can be directly utilized to reduce the complexity of compression with entropy encoding. Returning to FIG. 8, entropy encoding can employ Huffman codes on 256-symbol alphabets. Bit operations may be utilized for codewords (encodings of characters), but in this case, only twenty-five percent or fifty percent of the data needs to be entropy coded, while the remaining data can be saved uncompressed. More particularly, byte zero (b₀) and byte three (b₃) need not be compressed. Rather eight bits can be directly saved. Byte two (b₂) can be compressed with 256-symbol Huffman code to approximately 3.4 bits. Finally, byte one (b₁) can optionally be compressed with 256-symbol Huffman code to approximately 7.2 bits.

Traditional entropy encoding techniques are designed to operate with individual bits, which can limit throughput. However, it is possible to design techniques to minimize those per-bit operations while keeping the data arranged in bytes.

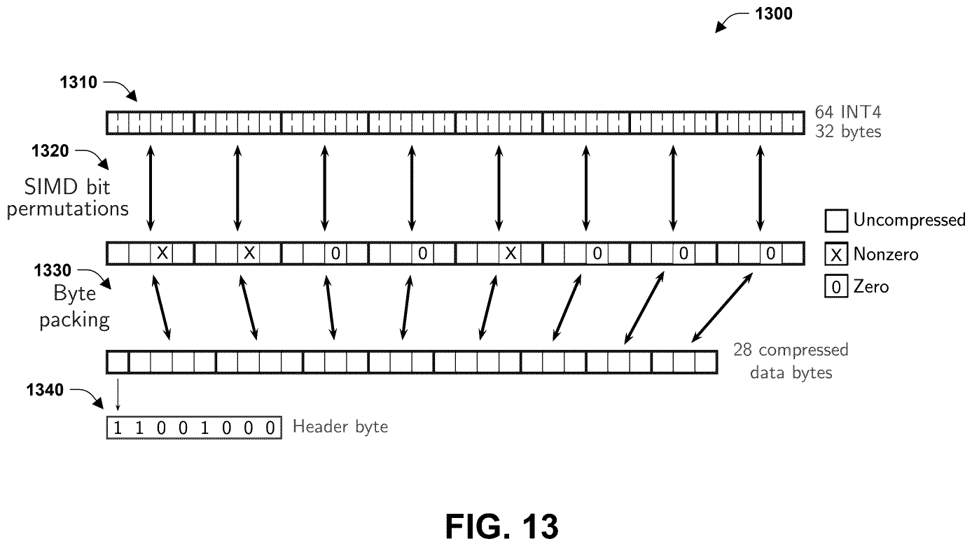

FIG. 13 depicts a technique 1300 for compressing rearranged data where data is arranged in a byte, with a header indicating zero-bytes that are removed from the byte stream. The technique can exploit weight distribution, such as the distribution of FIG. 5. Utilizing a bit rearrangement scheme such as that described with respect to FIG. 11. 8-bits in the byte labeled “b₂” have probability “Prob(b_{2,i}=0)=0.912, k=0,11, . . . 7,” which means the probability that all bits are zero is “Prob(b_{2,0}=0, b_{2,1}=0, . . . b_{2,7}=0) 0.912⁸=0.48≈0.5.” This means about 50% the bytes labeled “b₂” are expected to have 8 zero bits, and thus the occurrence of those zero bytes can be nearly optimally encoded with one bit. The compression method can work by creating groups of 8×4=32 bytes, adding one header byte to indicate which of those “b₂” bytes are zero, followed by the bytes except those that are indicated as zero in the header byte. FIG. 13 illustrates an example where a group of 8 sets of 32-bit words, at 1310, obtained after sign+magnitude conversion of 4-bit weight data followed by data reorganization described with respect to FIG. 11, which results in a set where five of the bytes labeled “b₂” have all bits equal to zero, and three of the bytes do not, at 1320. The header byte 1340 includes the bits indicating the position of non-zero “b₂” byte with a bit “1” and a bit “0” otherwise.

After saving the header byte, the encoder can save the data bytes, except the five “b₂” bytes with all zero bits. As a result, from an original 32 bytes, at 1310, the encoder uses one byte for header plus 27 data bytes, for a total of 28 compressed data bytes, resulting in 12.5% reduction in data size, at 1330. With this technique, a group of 32 data bytes can be represented with a number of bytes ranging from 25 to 33, with an average number of 29 bytes, and an average 11% reduction in data size. This process can be fast because the encoder and decoder do not have to process bit-aligned data. Only the header bits must be processed individually, but their number is fixed, and they effectively correspond to information on four bytes.

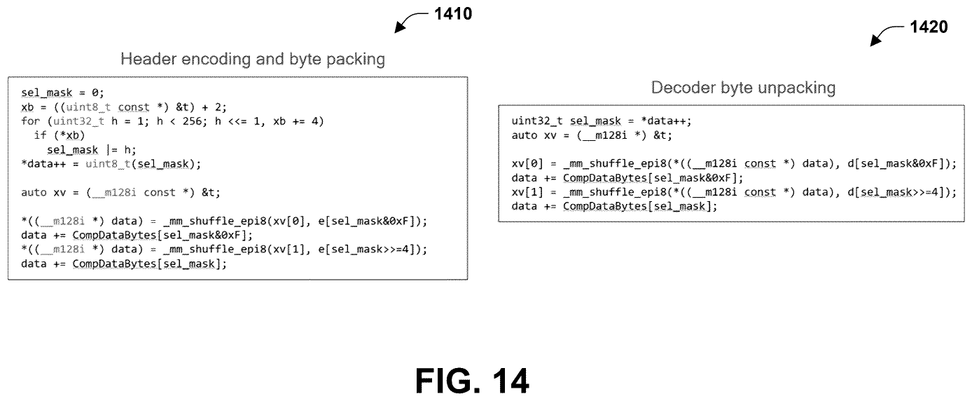

FIG. 14 illustrates an example of SIMD code implementing portions of the compression technique associated with FIG. 13. More specifically, FIG. 14 depicts header encoding and byte packing code 1410 and decoder byte unpacking code 1420. The process of removing and adding zero bytes can be effectively computed in parallel using byte shuffling SIMD operations, as shown in AVX SIMD code in FIG. 14. In that code, the encoder first determines the header byte and then uses tables to translate the header byte into a set of parameters for SIMD byte shuffling instructions, which employ byte permutations that move data bytes to the compressed data stream, while skipping the all-zero “b₂” bytes. The decoder also uses byte shuffling instructions that do the inverse permutations and also fill the all-zero “b₂” bytes with the correct value.

### Example Coding Methods

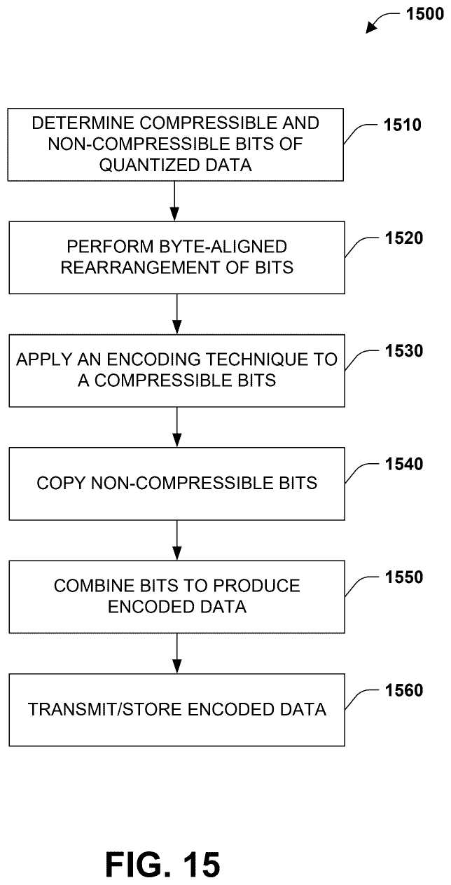

FIG. 15 depicts an example method 1500 for encoding data. In one aspect, method 1500 can be implemented by the computing device 100 of FIG. 1, and more specifically coding component 132 and encoder component 210 of FIGS. 2 and 3.

Method 1500 starts at block 1510 with determining compressible and non-compressible bits, which can be performed by compressible bit component 310 of FIG. 3. Bits can represent quantized data. Quantized data refers to data that has been converted from a continuous range of values into a finite set of discrete values. For example, a quantization process can convert floating point neural network weights into integers. In one particular instance, a 32-bit floating point number can be converted into 8-bit integers. Accordingly, the bits can represent integer values. Entropy can be determined for each bit, and based on the entropy, bits can be classified or categorized as compressible or non-compressible. In one instance, a threshold entropy can be set to classify bits as compressible or non-compressible.

Method 1500 continues to block 1520 with performing byte-aligned rearrangement of bits, which can be performed by the rearrangement component 320 of FIG. 3. In accordance with one aspect, quantized data, such as a weight, can be represented by a number of integer values that can be arranged into bit lines and stacked in order of significance, for example from the least significant bit to the most significant. For example, the top layer in the stack can hold the most important information while the bottom layer of the stack holds less important information, such as fine detail. Subsequently, the bit lines can be utilized to generate a stream of bytes capturing bits. In accordance with one implementation, such rearrangement can be performed by using shift operations by way of a shift matrix.

Method 1500 continues to block 1530 with applying an encoding technique to compressible bits associated with a bit, which can be performed by entropy encoding component 330 of FIG. 3. The encoding can correspond to entropy encoding, which is a lossless data compression technique that is based on statistical properties of the data being compressed. In one instance, Huffman coding can be employed, which involves analyzing the frequency of each symbol in data and generating variable-length binary codes for each symbol, for instance, such that shorter codes are assigned to frequent symbols and longer codes to infrequent symbols.

Method 1500 proceeds to block 1540 with copying non-compressible bits, which can be performed by copy component 340 of FIG. 3. Bits classified as non-compressible can be copied or saved without further transformation.

Method 1500 continues to block 1550 with combining bits to produce encoded data, which can be performed by union operator 350 of FIG. 3. Encoded bits can be combined with non-encoded bits to produce encoded data.

Method 1500 continues to block 1560 with transmitting, storing or both of the encoded data. Data can be encoded to reduce its size to facilitate transmission and storage. For example, reduced-size data can be transmitted faster and occupy less storage space than original data.

Note that FIG. 15 is just one example of a method, and other methods including fewer, additional, or alternative operations are possible consistent with this disclosure.

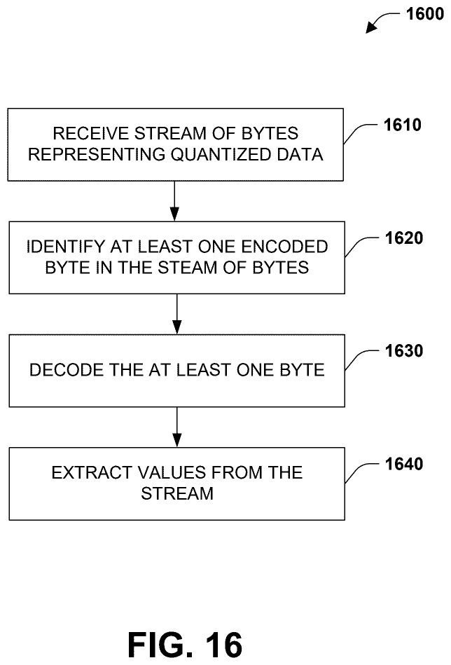

FIG. 16 depicts an example method 1600 for decoding encoded data. In one aspect, method 1600 can be implemented by the computing device 100 of FIG. 1, and more specifically coding component 132 and decoder component 220 of FIGS. 2 and 4.

Method 1600 starts at block 1610 with receiving a stream of bytes representing quantized data, which can be encoded data in which at least a portion of the bytes representing compressible bits are encoded.

Method 1600 continues at block 1620 with identifying at least one byte in the stream of bytes that is encoded. In accordance with one aspect, header information can indicate which, if any, bytes are encoded.

Method 1600 continues at block 1630 with decoding at least one byte comprising encoded data. In accordance with one aspect, decoding can correspond to reversing an encoding process to reveal original unencoded data. As a result, an unencoded byte stream or sequence is produced.

Method 1600 continues at block 16410 with extracting values from the unencoded byte stream. Original data may have been rearranged and byte aligned. Data extraction component 420 can reverse a rearrangement process to produce original data. Output can be original integer values of neural network parameters such as weights.

Note that FIG. 16 is just one example of a method, and other methods including fewer, additional, or alternative operations are possible consistent with this disclosure.

### Example Clauses

Implementation examples are described in the following numbered clauses:

Clause 1: A method of encoding data, comprising: determining bits of quantized data that are compressible and non-compressible based on one or more properties of the quantized data; performing a byte-aligned rearrangement of the bits of the quantized data; applying a compression technique to at least one compressible bit; and copying at least one non-compressible bit.

Clause 2: The method of Clause 1, wherein determining the bits of the quantized data that are compressible and non-compressible further comprises determining entropy of the bits of the quantized data.

Clause 3: The method of Clauses 1-2, further comprising: comparing the entropy of the bits of the quantized data to a threshold; determining that a bit of the bits satisfies the threshold; and identifying the bit as compressible.

Clause 4: The method of Clauses 1-3, wherein performing the byte-aligned rearrangement, further comprises separating the bits into bit line bytes based on bit position.

Clause 5: The method of Clauses 1-4, further comprising ordering bytes from least to most significant based on bit significance.

Clause 6: The method of Clauses 1-5, wherein least significant bits have higher entropy than most significant bits.

Clause 7: The method of Clauses 1-6, wherein performing the byte-aligned rearrangement of the bits further comprises performing bit shifts.

Clause 8: The method of Clauses 1-7, further comprising performing bit shifts of multiples of seven.

Clause 9: The method of Clauses 1-8, further comprising applying entropy coding as the compression technique on the at least one compressible bit.

Clause 10: The method of Clauses 1-9, wherein the entropy coding is Huffman coding.

Clause 11: A method of decoding coded data, comprising: receiving a stream of bytes that represent quantized data; identifying at least one compressed byte in the stream of bytes; decompressing the at least one compressed byte; and extracting bits from the stream of bytes that encode the quantized data.

Clause 12: An apparatus comprising: one or more memories; processing circuitry in communication with the one or more memories, the processing circuitry configured to perform a method in accordance with any one of Clauses 1-11.

Clause 13: A processing system, comprising: a memory comprising computer-executable instructions; and a processor configured to execute the computer-executable instructions and cause the processing system to perform a method in accordance with any one of Clauses 1-11.

Clause 14: A processing system, comprising means for performing a method in accordance with any one of Clauses 1-11.

Clause 15: A non-transitory computer-readable medium storing program code for causing a processing system to perform the steps of any one of Clauses 1-11.

Clause 16: A computer program product embodied on a computer-readable storage medium comprising code for performing a method in accordance with any one of Clauses 1-11.

### Additional Considerations

The preceding description is provided to enable any person skilled in the art to practice the various embodiments described herein. The examples discussed herein are not limiting of the scope, applicability, or embodiments set forth in the claims. Various modifications to these embodiments will be readily apparent to those skilled in the art, and the generic principles defined herein may be applied to other embodiments. For example, changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database, or another data structure), ascertaining and the like. Also, “determining” may include receiving (e.g., receiving information), accessing (e.g., accessing data in a memory) and the like. Also, “determining” may include resolving, selecting, choosing, establishing and the like.

The methods disclosed herein comprise one or more steps or actions for achieving the methods. The method steps and/or actions may be interchanged with one another without departing from the scope of the claims. In other words, unless a specific order of steps or actions is specified, the order and/or use of specific steps and/or actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components with similar numbering.

The following claims are not intended to be limited to the embodiments shown herein, but are to be accorded the full scope consistent with the language of the claims. Within a claim, reference to an element in the singular is not intended to mean “one and only one” unless specifically so stated, but rather “one or more.” Unless specifically stated otherwise, the term “some” refers to one or more. No claim element is to be construed under the provisions of 35 U.S.C. § 112(f) unless the element is expressly recited using the phrase “means for” or, in the case of a method claim, the element is recited using the phrase “step for.” All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

What is claimed is:

1. A method of encoding data, comprising:
determining bits of quantized data that are compressible and non-compressible based on one or more properties of the quantized data;
performing a byte-aligned rearrangement of the bits of the quantized data;
applying a compression technique to at least one compressible bit; and
copying at least one non-compressible bit.

2. The method of claim 1, wherein the quantized data correspond to integer representations of neural network weights.

3. The method of claim 1, wherein determining the bits of the quantized data that are compressible and non-compressible further comprises determining entropy of the bits of the quantized data.

4. The method of claim 3, further comprising:
comparing the entropy of the bits of the quantized data to a threshold;
determining that a bit of the bits satisfies the threshold; and
identifying the bit as compressible.

5. The method of claim 1, wherein performing the byte-aligned rearrangement, further comprises separating the bits into bit line bytes based on bit position.

6. The method of claim 5, further comprising ordering bytes from least to most significant based on bit significance.

7. The method of claim 6, wherein least significant bits have higher entropy than most significant bits.

8. The method of claim 1, wherein performing the byte-aligned rearrangement of the bits further comprises performing bit shifts.

9. The method of claim 1, wherein performing the byte-aligned rearrangement further comprises executing at least one single instruction multiple data (SIMD) shift operation.

10. The method of claim 1, further comprising applying entropy coding as the compression technique on the at least one compressible bit.

11. The method of claim 10, wherein the entropy coding is Huffman coding.

12. An apparatus configured to encode data, the apparatus comprising:
one or more memories;
processing circuitry in communication with the one or more memories, the processing circuitry configured to:
determine bits of quantized data that are compressible and non-compressible based on one or more properties of the quantized data;
perform a byte-aligned rearrangement of the bits of the quantized data;
apply a compression technique at least one compressible bit; and
copy at least one non-compressible bit.

13. The apparatus of claim 12, wherein the quantized data correspond to integer representations of neural network weights.

14. The apparatus of claim 12, wherein the processing circuitry configured to determine the bits of quantized data that are compressible and non-compressible is further configured to determine entropy of the bits of the quantized data.

15. The apparatus of claim 14, wherein the processing circuitry is further configured to determine that at least one bit of the bits of the quantized data is compressible based on entropy of the bit satisfying a threshold.

16. The apparatus of claim 15, wherein the processing circuitry configured to perform the byte-aligned rearrangement is further configured to separate bits into bit line bytes based on bit position.

17. The apparatus of claim 16, further comprising ordering bytes from least to most significant based on bit significance, wherein least significant bits have higher entropy than most significant bits.

18. The apparatus of claim 12, wherein the processing circuitry configured to perform the byte-aligned rearrangement of the bits is further configured to perform bit shifts.

19. The apparatus of claim 12, wherein the compression technique is entropy coding.

20. A method of decoding coded data, comprising:
receiving a stream of bytes that represent quantized data;
identifying at least one compressed byte in the stream of bytes;
decompressing the at least one compressed byte; and
extracting bits from the stream of bytes that encode the quantized data.
